(19) United States
(12) Patent Application Publication
(10) Pub. No.: US 2025/0358979 A1
(43) Pub. Date: Nov. 20, 2025

(54) DATA CENTER FACILITY WITH HYBRID COOLING INFRASTRUCTURE

(71) Applicant: Switch, Ltd., Las Vegas, NV (US)

(72) Inventor: Rob ROY, Las Vegas, NV (US)

(21) Appl. No.: 19/213,614

(22) Filed: May 20, 2025

Related U.S. Application Data
(60) Provisional application No. 63/649,810, filed on May 20, 2024.
(60) Provisional application No. 63/747,234, filed on Jan. 20, 2025.
(60) Provisional application No. 63/775,860, filed on Mar. 21, 2025.

(51) Int. Cl. H05K 7/20

(52) U.S. Cl. CPC H05K 7/2079; H05K 7/20745

(57) ABSTRACT

A data center facility includes a plurality of insulated chambers each defining a compartment and having at least one front door and at least one rear door opposite the front door. A plurality of electronic equipment cabinets each positioned in the compartment of one of the chambers. The electronic equipment cabinets are configured to hold a plurality of electronic devices. The compartment of each of the chambers is divided into a front chamber space and a rear chamber space. An air cooling assembly is configured to emit cooled air into the front chamber space to cool the electronic devices, and to remove air that has been heated by the electronic devices from the rear chamber space. A liquid coolant delivery assembly is configured to releasably connect to a liquid cooling unit of the electronic devices for cooling the electronic devices.

### CROSS-REFERENCE TO RELATED APPLICATIONS

The present application claims priority to U.S. Provisional Patent Application Ser. No. 63/649,810, filed May 20, 2024 and entitled “Data Center Facility with Hybrid Cooling Infrastructure,” U.S. Provisional Patent Application Ser. No. 63/747,234, filed Jan. 20, 2025 and entitled “Data Center Facility with Hybrid Cooling Infrastructure,” and U.S. Provisional Patent Application Ser. No. 63/775,860, filed Mar. 21, 2025 and entitled “Data Center Facility with Hybrid Cooling Infrastructure.” the entireties of which are all incorporated by reference herein.

### BACKGROUND OF THE DISCLOSURE

### 1. Field of the Disclosure

The present disclosure relates to electronic equipment data center facility designs and methods of making and using the same.

### 2. Related Art

This section provides background information related to the present disclosure which is not necessarily prior art.

Data centers are known for storing electronic devices, such as internet servers, which are owned by one or more entities. Typically, a data center facility includes numerous rows of cabinets which store the electronic devices. The cabinets are equipped such that only the owners of the electronic devices contained therein, and potentially the facility operator, have access to interior compartments of the cabinets. In many instances, the owner of the facility manages the installation and removal of servers within the facility, and is responsible for maintaining utility services that are needed for the servers to operate properly. These utility services typically include providing electrical power for operation of the servers, providing telecommunications ports that allow the servers to connect to transmission grids that are typically owned by telecommunication carriers, and providing air-conditioning services that maintain temperatures in the facility at sufficiently low levels for reliable operation of the electronic devices.

There are some well-known common aspects to the designs of these facilities. For example, it is known to position the cabinets in rows, and further to have parallel rows of the cabinets configured back-to back so that each row generally forces heat from the electronic devices toward a similar area, known as a hot aisle, as that aisle generally contains warmer air that results from the forced heat from the electronic devices. In front of the equipment is thus established a cold aisle. Air from the hot aisle is then removed, cooled, and emitted back to the cold aisle via a cooling cycle.

Advancements in microprocessor chip technology, driven by demand for artificial intelligence (AI), are now allowing chip manufacturers to create more powerful chips on smaller chip units, which in turn creates more heat at faster rates and in higher densities. As a solution to this, liquid cooling technologies have been developed for managing heat dispersal with a direct-to-chip approach. There remains a need for further improvements to data center facility infrastructure for the most effective and efficient use of resources to cool electrical devices like internet servers.

### SUMMARY OF THE DISCLOSURE

According to an aspect of the disclosure, a data center facility includes a plurality of insulated chambers each defining a compartment and having at least one front door and at least one rear door opposite the front door. An electronic equipment cabinet is positioned in the compartment of each chamber. The electronic equipment cabinets are configured to house a plurality of electronic devices. The compartment of each chamber is divided into a front chamber space and a rear chamber space. An air cooling assembly is configured to emit cooled air into the front chamber space to cool the electronic devices, and to remove air that has been heated by the electronic devices from the rear chamber space. A liquid coolant delivery assembly is configured to releasably connect to a liquid cooling unit of the electronic devices for cooling the electronic devices.

According to another aspect of the disclosure, a data center facility includes a plurality of insulated chambers that each define a compartment. An electronic equipment cabinet is positioned in the compartment of each insulated chamber. The electronic equipment cabinets are configured to house a plurality of electronic devices. A liquid coolant delivery assembly is configured to releasably connect to liquid cooling units of the electronic devices for cooling the electronic devices. The liquid coolant delivery assembly includes a plurality of liquid coolant delivery systems for connecting to a plurality of the cooling units of the electronic devices to provide different cooling effects for respective electronic devices.

According to another aspect of the disclosure, a data center facility includes a plurality of insulated chambers that each define a compartment. An electronic equipment cabinet is positioned in the compartment of each insulated chamber. The electronic equipment cabinets are configured to house a plurality of electronic devices. Each of the insulated chambers includes an insulated dividing panel that is sealingly positioned in the compartment of the insulated chamber about the electronic equipment cabinet and divides the compartment into a front chamber space and a rear chamber space. A plurality of air cooling assemblies are each positioned above one of the chambers and configured to emit cooled air into the front chamber space to cool the electronic devices, and to remove air that has been heated by the electronic devices from the rear chamber space.

According to another aspect of the disclosure, a data center facility includes a plurality of insulated chambers that each define a compartment and each have at least one door. The plurality of insulated chambers are positioned in a plurality of rows positioned in parallel relationship with one another. An electronic equipment cabinet is positioned in the compartment of each insulated chamber. The electronic equipment cabinets are configured to house a plurality of electronic devices. The at least one door of each chamber includes a pair of front doors and a pair of rear doors. The doors comprising each pair of doors are configured to rotate in opposite directions from one another between an open position and a closed position. Edges of the doors are configured to be positioned adjacent to, and aligned with one another when the doors are in the closed position.

The data center facility infrastructure therefore has a hybrid air and liquid cooling mechanism to efficiently use resources and provide effective power, connectivity, and cooling to high heat density electronic devices as well as fail-safe redundancy. The data center facility infrastructure allows electronic device owners to interchangeably install their preferred electronic equipment cabinets, preferred electronic devices, and preferred liquid cooling technology within an insulated chamber that houses their electronic equipment cabinets. The subject data center facility is also beneficial in that it only requires a single insulated panel to be positioned inside the insulated chamber at its midline to provide heat insulated separation of the front and rear chamber spaces to provide efficient air cooling.

### BRIEF DESCRIPTION OF THE DRAWINGS

These and other advantages of the present disclosure will be more readily understood by reference to the following description in combination with the accompanying drawings wherein:

FIG. 1 is a perspective view of a first embodiment of a data center facility;

FIG. 2 is a perspective view of rows of chambers and an associated support frame of the data center facility;

FIG. 3 is a perspective view of a plurality of chambers and associated support frame, cooling lines and power distribution units of the data center facility;

FIG. 4 is a front view of a plurality of chambers of the data center facility, illustrating front doors of two of the chambers in an open position;

FIG. 5 is a side, cross-sectional and schematic illustration of a chamber and associated support frame, cooling lines, HVAC units and power distribution units of the data center facility, illustrating circulation of air through the chamber and HVAC unit;

FIG. 6 is a side view of a catwalk, cooling lines and the support frame of the data center facility;

FIG. 7 is a perspective view of a catwalk, cooling lines, power distribution units and the support frame of the data center facility;

FIG. 8 is a perspective view of ladder racks and the support frame of the data center facility;

FIG. 9 is a perspective view inside a cabinet of the data center facility, illustrating brush wire cutouts for receiving wires and lines into the cabinet;

FIG. 10 is a schematic top view illustrating different alternate cooling arrangement embodiments for the data center facility;

FIG. 11 is a front view of an interior of a chamber of the data center facility, illustrating an arrangement of electronic devices;

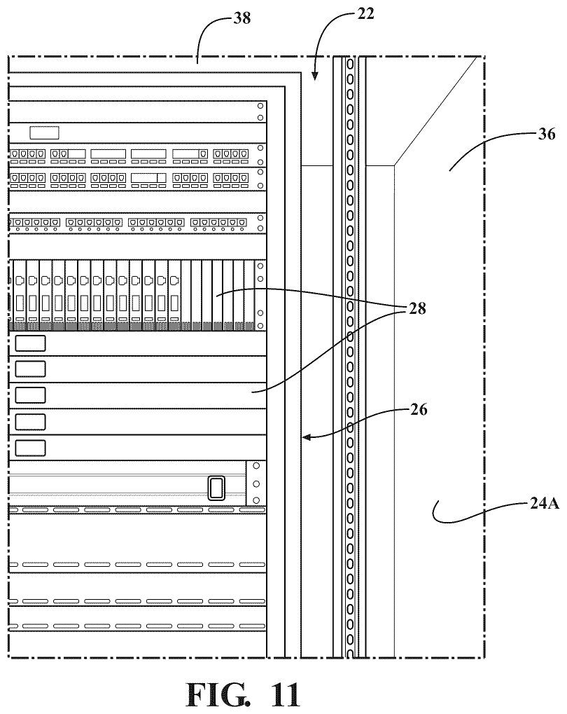

FIG. 12 is a perspective view of chambers, cooling lines, a support frame and an arrangement of network trays of the data center facility;

FIG. 13 is a perspective view of chambers, a support frame and an arrangement of condensate drip trays of the data center facility;

FIG. 14 is a perspective view of a catwalk, cooling lines, HVAC units, and power distribution cables of the data center facility;

FIG. 15 is a perspective view of a mailbox component of the data center facility; and

FIG. 16 is a perspective view of an arrangement of ladders inside chambers.

### DETAILED DESCRIPTION OF THE ENABLING EMBODIMENTS

Example embodiments will now be described more fully with reference to the accompanying drawings. In general, the subject embodiments are directed to data centers used to power, cool, connect, and secure electronic devices such as internet servers. However, the example embodiments are only provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

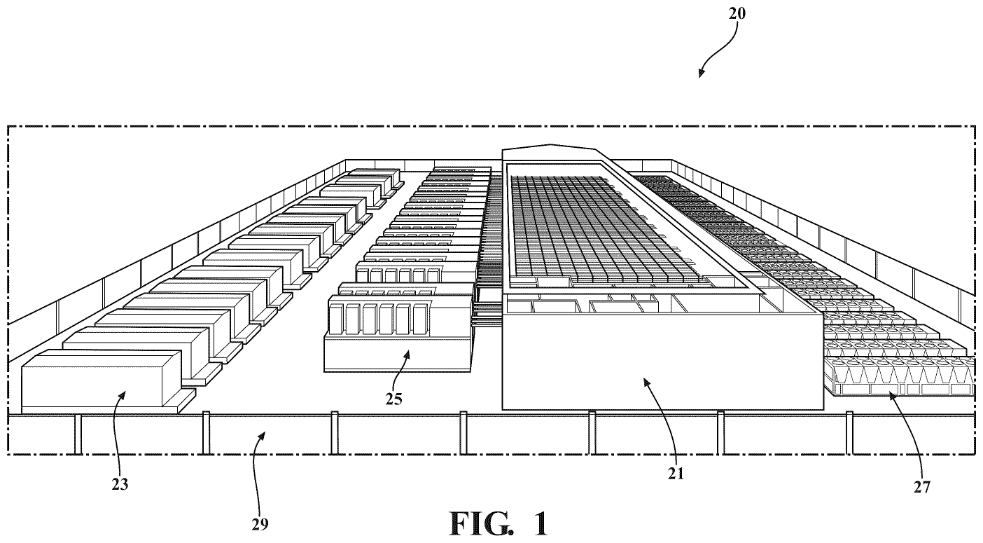

Referring to the figures, wherein like numerals indicate corresponding parts throughout the several views, embodiments of a data center facility 20 are provided. As shown in FIG. 1, according to embodiments, the data center facility 20 includes a building 21 for securely protecting electronic equipment contained therein from unauthorized users and the external environment. The facility 20 also includes one or more generators 23 for generating electricity. The facility 20 may also be connected to other sources of electricity, like a local power grid. The facility also includes one or more power distribution units 25 for managing and distributing power to facility equipment. The facility also includes one or more chillers 27 for providing cooled water to facility equipment. The facility may also include a security perimeter 29 about the facility 20 for preventing unauthorized access to the facility 20.

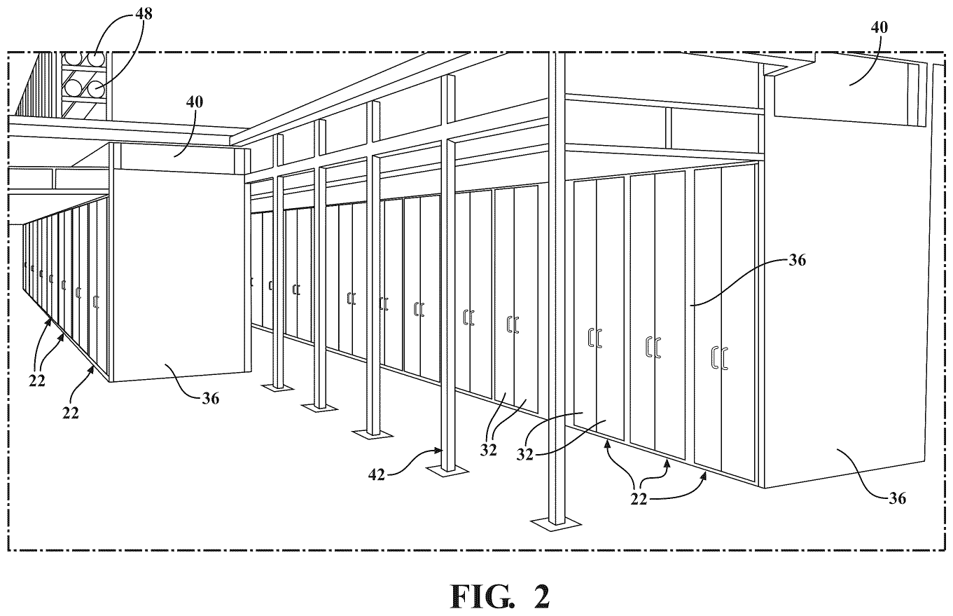

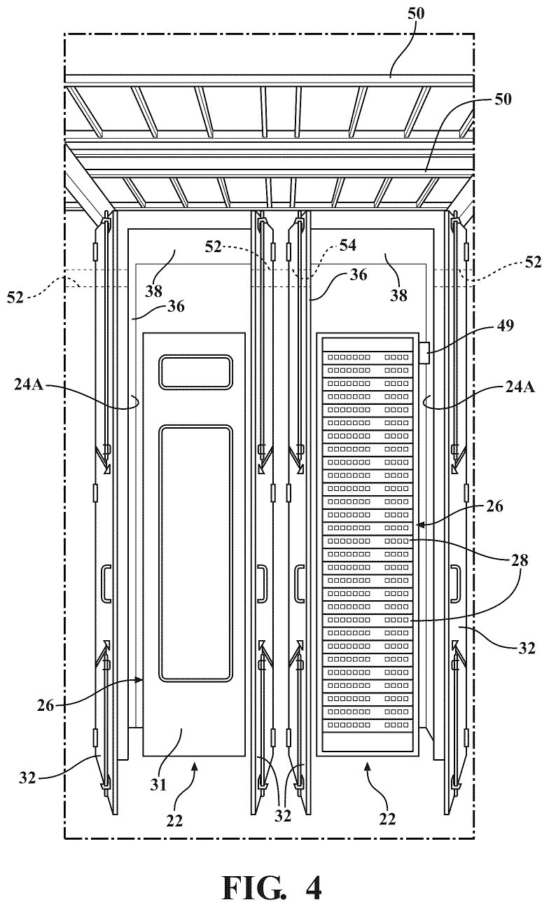

As shown in FIGS. 2-5, the data center facility 20 has a plurality of insulated chambers 22 that each have a compartment 24A, 24B which contains an electronic equipment cabinet 26. The electronic equipment cabinets 26 are each configured to hold heat producing electronic devices 28, such as internet servers. As shown, in FIG. 4, the cabinets 26 may each have front and/or rear panels 31 for closing the cabinets 26. The chambers 22 thermally and sonically insulate the electronic devices 28 contained therein from the external environment by providing an insulated environment to permit a temperature controlled climate within the compartment 24A, 24B to be selectively controlled. According to embodiments, humidity may also be controlled in the chambers 22. The chambers 22 are positioned side-by-side to one another in a series of rows. Any number of chambers 22 may be in each row, and any number of rows may be utilized.

According to embodiments, the electronic devices 28 contained in the chambers 22 may be owned by various owners, and the data center facility 20 may be responsible for managing the chambers 22 to provide an optimized environment for the electronic devices 28. As will be discussed in further detail below, according to embodiments, the electronic devices 28 may include advanced microprocessors for use with AI technologies, and may include interchangeable liquid cooling systems, i.e., CDUs (coolant distribution units), for heat dissipation purposes.

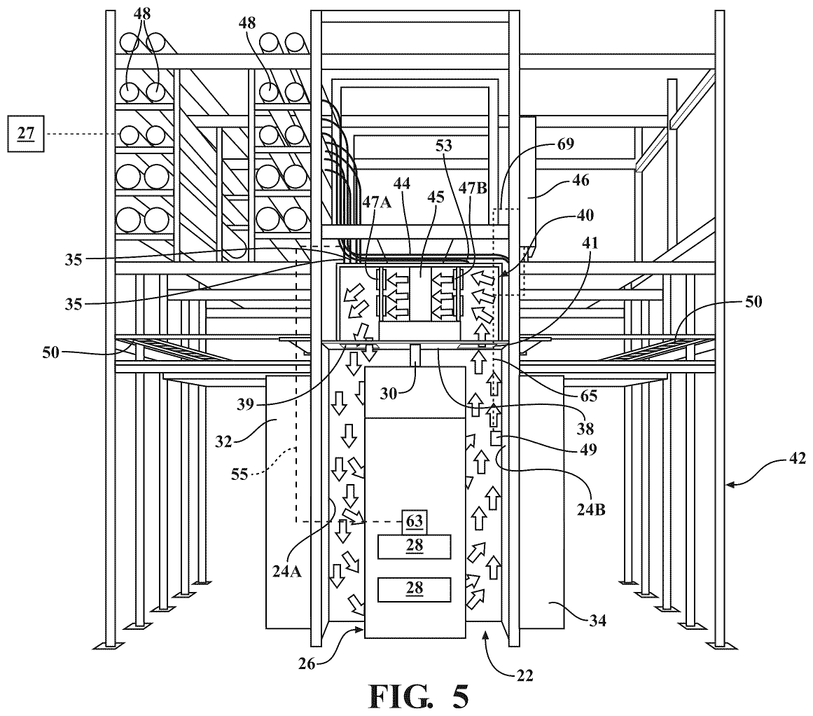

The electronic equipment cabinets 26 are positioned centrally within the compartments of the insulated chambers 22. As best shown in FIG. 5, an insulated dividing panel 30 may sealingly surround the electronic equipment cabinet 26 to divide the insulated chamber 22 into a front chamber space 24A and a rear chamber space 24B. As will be explained in further detail below, the electronic devices 28 in the electronic equipment cabinet 26 are configured to draw in cooled air from the front chamber space 24A, and emit heated air into the rear chamber space 24B.

As shown in FIGS. 2 and 5, each of the insulated chambers 22 has one or more insulated front doors 32 for selectively closing the front chamber space 24A, and one or more insulated rear doors 34 opposite the front doors 32 for selectively opening and closing the rear chamber space 24B. The front and rear doors 32, 34 therefore allow operators to selectively gain access to the front chamber space 24A or rear chamber space 24B to manage equipment contained therein without disrupting other chambers 22. A pair of insulated sidewalls 36 extend between the front and rear doors 32, 34. An insulated ceiling panel 38 closes a top of the insulated chambers 22.

According to some embodiments, each of the insulated chambers 22 may share at least one sidewall 36 with another of the insulated chambers 22 to provide a compact arrangement, but in a preferred configuration the insulated chambers 22 have standalone sidewalls 36 such that additional insulated chambers 22 may be deployed in a data center facility 20 on an as-needed basis. According to embodiments, the doors 32, 34 may be 9 feet tall, while the chambers are 11 feet tall, thus permitting cabinets 26 to be rolled and docked therein easily. The door openings may have dimensions of approximately 108″ H×33.75″ W, and the internal dimensions of the chambers 22 may be approximately 132″ H×42″ W×85″ D to support various cabinet 26 geometries. According to embodiments, the doors 32, 34 are configured as dual “French style” doors, which occupy less space upon opening than a single door which occupies the same opening. This provides improved clearance in the walkway in front of the door 32, 34, which permits chambers 22 on both sides of the walkway to be accessed at once. Door and opening dimensions may vary based on specific needs.

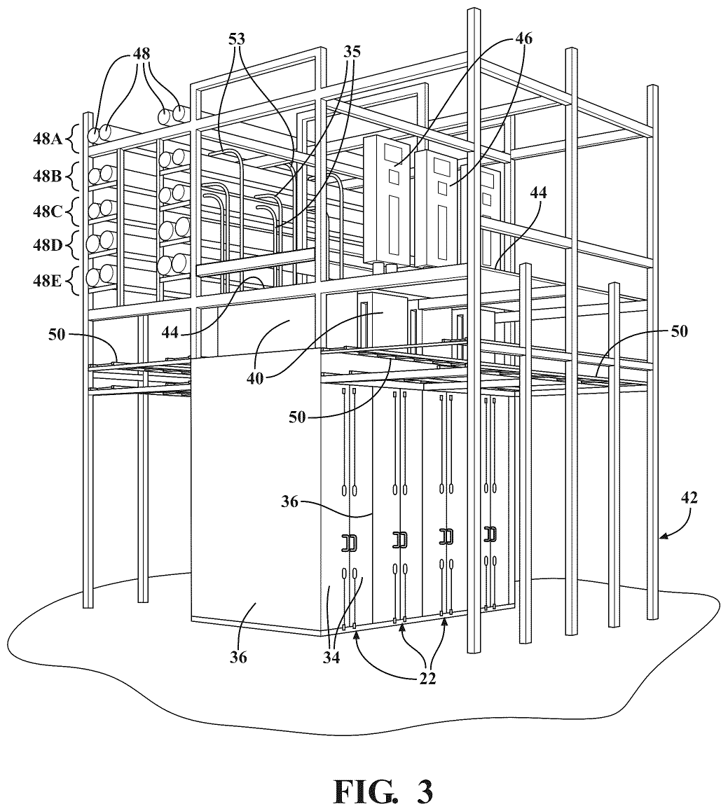

As best shown in FIG. 5, each of the ceiling panels 38 of the insulated chambers 22 defines a front cooling opening 39 (schematically shown) extending into the front chamber space 24A and a return air opening 41 (schematically shown) extending into the rear chamber space 24B. As shown in FIGS. 3 and 5, one or more heating ventilation and air conditioning (HVAC) units 40 are removably positioned above each of the ceiling panels 38 of the insulated chambers 22 such that the one or more HVAC units 40 are positioned above the chamber 22. The HVAC units 40 are configured to cool, filter, humidify, and dehumidify (and combinations thereof) the air contained therein. One or more supply fans 47A of the HVAC units 40 emit/allow cold air to fall into the front chamber space 24A of each of the insulated chambers 22 through the cooling opening 39. Each of the HVAC units 40 may include at least two evaporator coils 45 (schematically shown) for cooling air prior to passing it into the front chamber space 24A. Furthermore, the HVAC units 40 each may have one or more intake fans 47B for drawing heated air from the rear chamber space 24B such that the heated air can be cooled, filtered, humidified, and/or dehumidified in the HVAC unit 40 and cycled back into the front compartment 24A, 24B of the insulated chamber 22. According to embodiments, only the supply fans 47A are used without use of the intake fans 47B. As illustrated in the figures, the HVAC units 40 are compact in size, and according to embodiments, multiple HVAC units 40 may each be fluidly connected to a single chamber to provide a redundant cooling effect, to scale air cooling as needed, and to serve as a backup cooling arrangement in the event that one fails. According to this arrangement, only a single evaporator coil 45 may be used per HVAC unit 40. The ceiling panels 38 may be configured to support the weight of any number of HVAC units 40. Furthermore, the capacity of the HVAC units 40 may vary from cabinet 26 to cabinet 26 to optimize the provided cooling effect. Furthermore, the case/shell of the HVAC units 40 may be configured to receive interchangeable coils 45 and fans 47A, 47B in a modular manner. The location of the HVAC units above the chambers 20 provides ample space and convenient access for substituting components of the HVAC units 40.

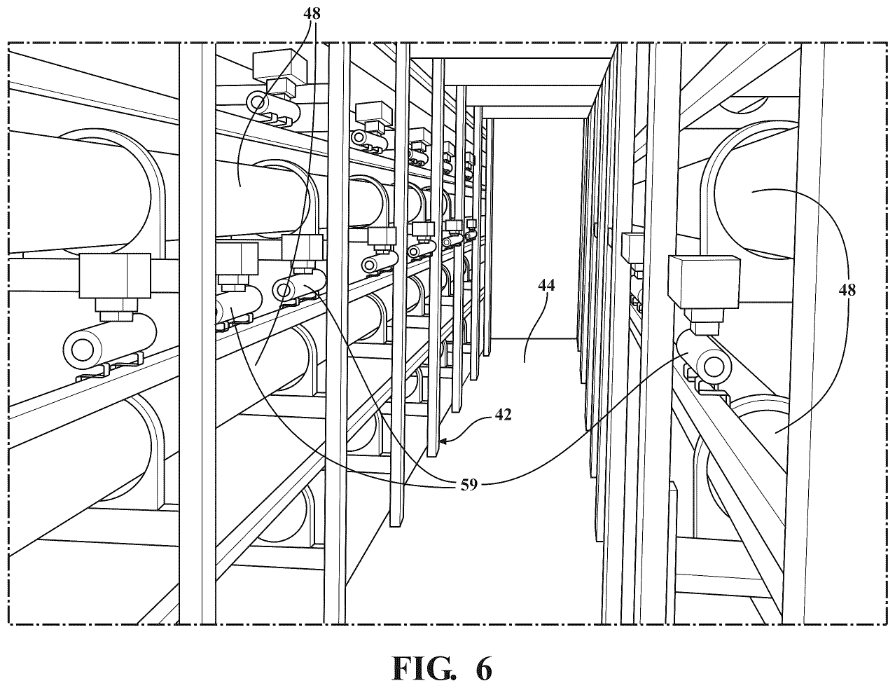

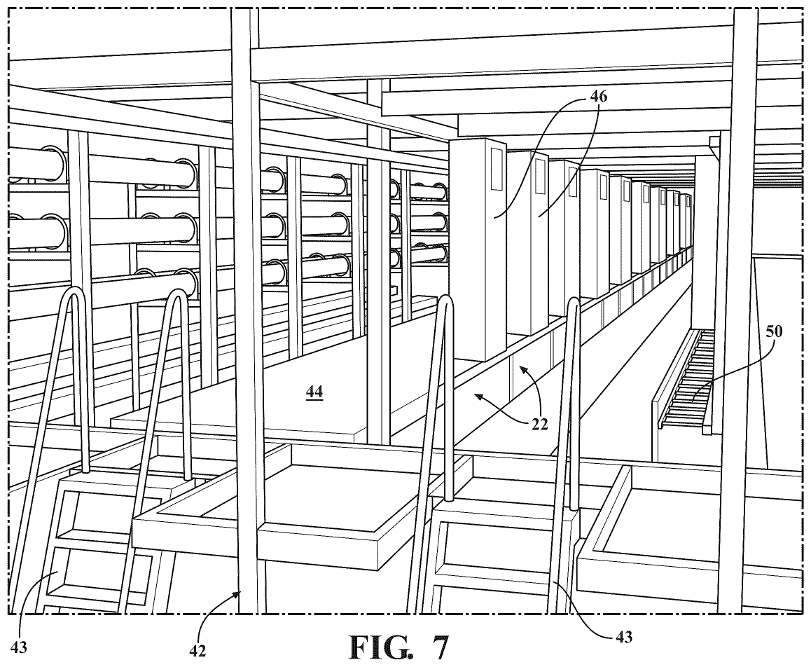

As shown throughout the figures, a support frame 42 of steel or other strong material is positioned about and above the insulated chambers 22 for holding equipment and providing access to a region above the insulated chambers 22. The support frame 42 may have various sizes and configurations. As best shown in FIGS. 6, 7 and 14, catwalks 44 are secured to the support frame 42 above the insulated chambers 22 and HVAC units 40 to permit users to access the region above the insulated chambers 22 for deployment, removal, or maintenance of HVAC units 40, power units 46, and cooling liquid lines 48, 53 (discussed below). Ladders 43 extend vertically between the catwalks 44 and a floor of the facility 20 to permit operators to access the catwalks 44. As shown in FIG. 3, the catwalks 44 may be positioned laterally relative to the chambers 22 and HVAC units 40 rather than above them.

The facility 20 may have two or more floors. According to embodiments, the second floor may include features such as a maintenance catwalk 44, power unit 46 connections, mechanical valving 59 and access to the top of the chambers 22 for maintenance or replacement. A fire suppression system may be located on either or both floors. The first floor (ground floor) is set up to provide convenient access to the chambers 22 on both sides. The overall floor-mounted configuration of the support frame 42 reduces weight limitations. The support frame 42 may be custom designed and manufactured for specific needs. Because all cooling and power equipment assemblies are located above the chambers 22, maintenance tasks are performed above chambers 22, which limits the frequency at which maintenance works have to be on the floor near the electronic devices 28.

As shown in FIGS. 3, 5 and 7, the power units 46 are supported on and connected to the support frame 42 above the insulated chambers 22 for providing power to the HVAC units 40 and electronic devices 28 contained in the insulated chambers 22. As shown, the power units 46 are compact, thus permitting any number of power units 46 to be employed in association with each chamber 22 as needed. Furthermore, the location of the power units 46 and associated lines provides optimized line distances. As schematically shown in FIG. 5, a plurality of HVAC power cables 69 extend from the power units to the HVAC units 40 to power the HVAC units 40.

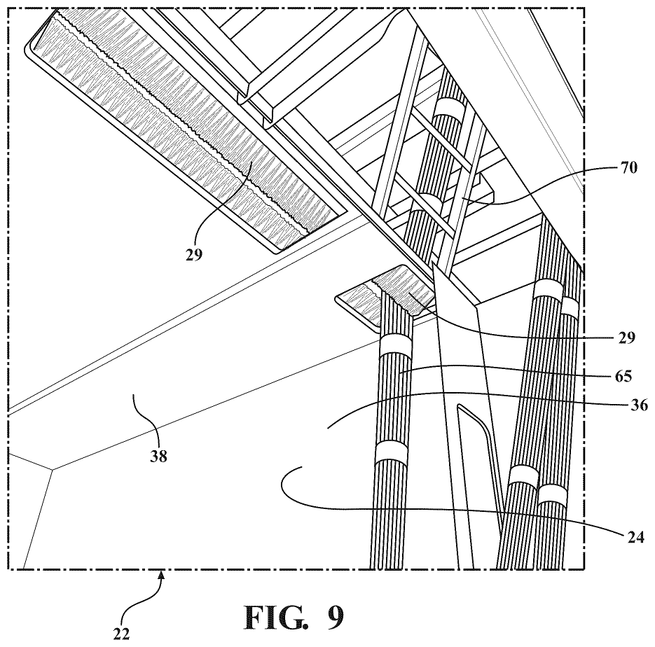

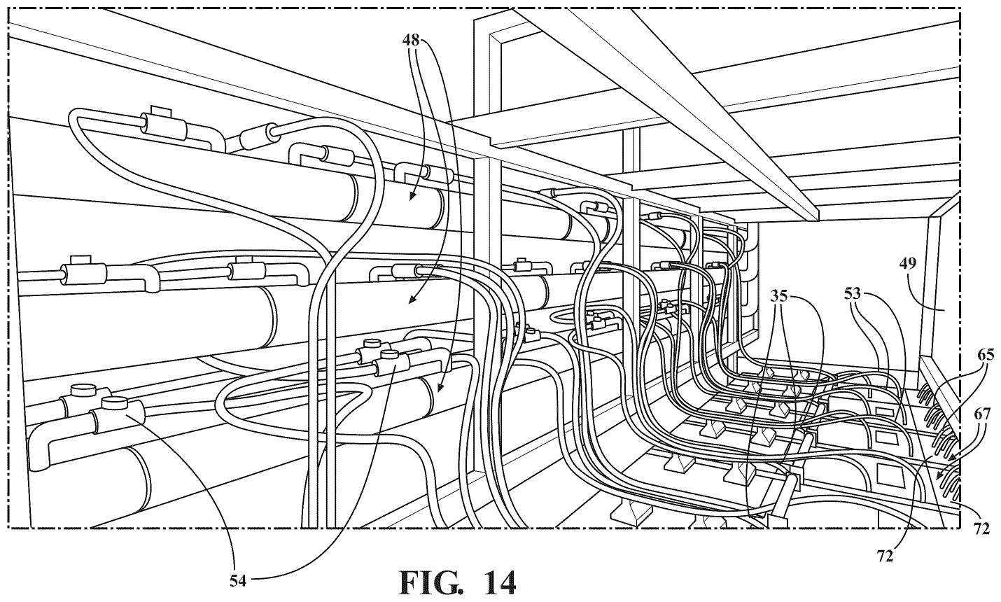

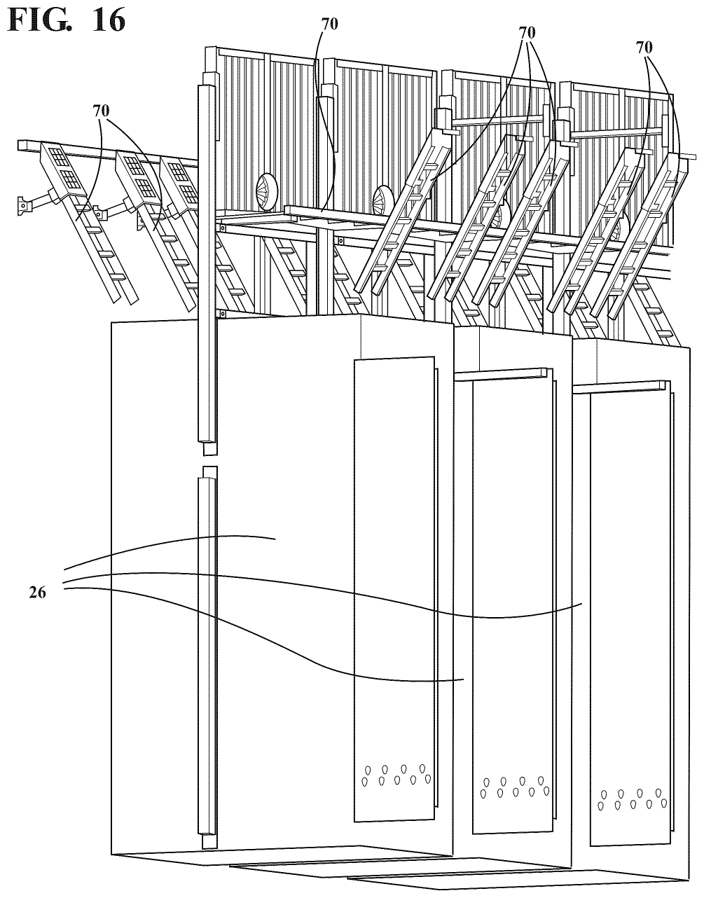

Cabinet power distribution units (PDUs) 49 (schematically shown in FIG. 4) may be positioned on the sidewalls 36 in the front chamber space 24A or the rear chamber space 24B of the insulated chambers 22 for distributing power to the electronic devices 28. Distribution power cables 65 extend from the power units 46 to the cabinet PDUs 49 to connect the power units 46 and cabinet PDUs 49. As shown in FIG. 14, the power distribution cables 65 each extend through one of a plurality of mailbox components 67 located above the chambers 22. Redundant power units 46 may be provided for each of the insulated chambers 22 to continue to provide power to the electronic devices 28 contained in the insulated chamber 22 in the event of failure of one of the power units 46. As best shown in FIG. 9, ladder racks 70 and other cable management components to support cables and other lines may be positioned above the cabinets 26 and/or chambers 22 for guiding lines and cables into the chamber 22 and/or cabinets 26. Above-rack brush wire cutouts 29 may be positioned near the ladder racks 70 to permit hoses/cables to pass therethrough at various locations of the support frame 42. FIG. 16 shows an arrangement of ladder racks 70 for being located in chambers 22 above cabinets 26 for holding cables and other lines above the cabinets 26 inside the chambers 22.

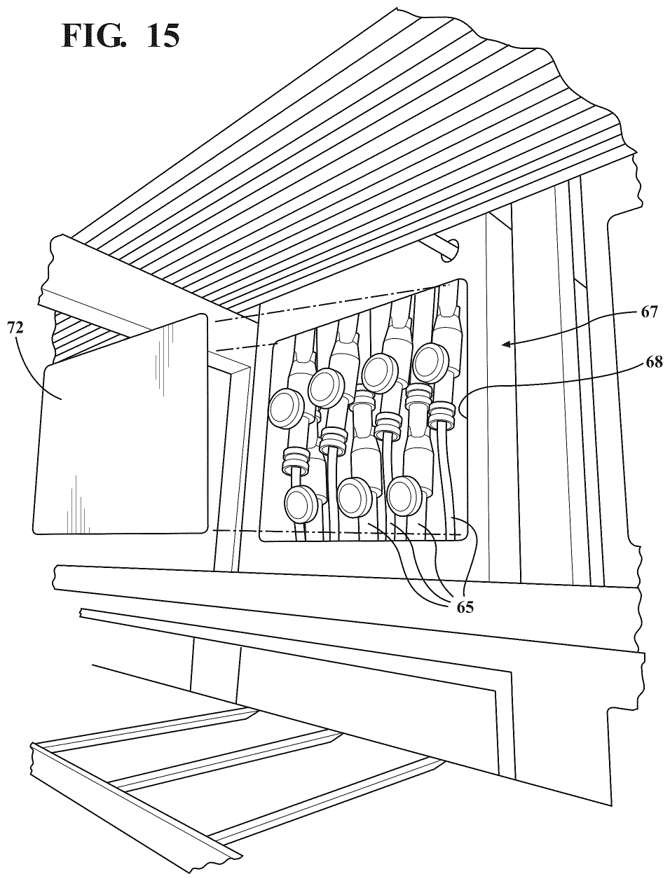

FIG. 15 shows another arrangement of a mailbox component 67 which is used to store and conceals wires, lines 65 and/or associated connecting components and valves. The mailbox component 67 has a mailbox compartment 68 which houses the components and a removeable cover 72 which closes the compartment 68 to protect the components. Mailbox components 67 may be used to house various types of lines, wires and valves at various locations of the facility 20.

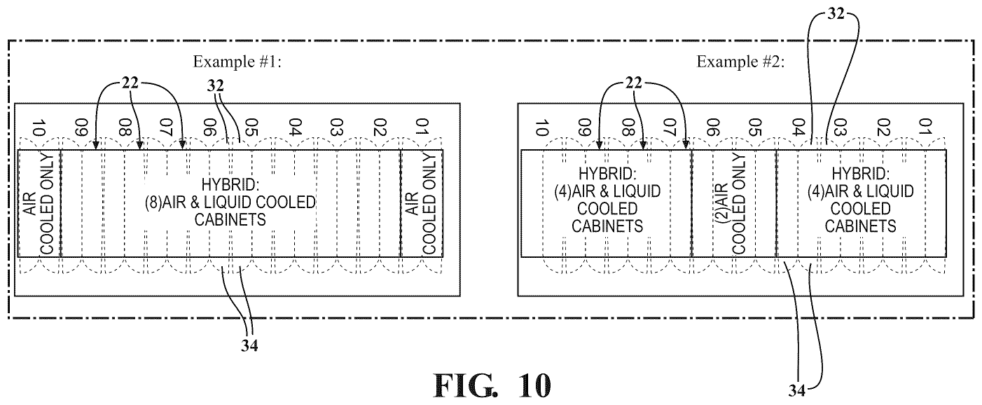

As will be discussed in further detail below, the data center facility 20 includes an arrangement of cooling lines 48, 53, 35 for being connected to the interchangeable liquid cooling systems of the electronic devices 28 and the HVAC units 40. This liquid cooling arrangement is supplementary to the air cooling arrangement of the HVAC units 40, thus providing a hybrid cooling arrangement for the chambers 22. As illustrated in FIG. 10, combinations of the liquid and air cooling systems may be used chamber 22 to chamber 22. For example, some chambers 22 may utilize hybrid cooling, some may utilize liquid cooling alone, and some may utilize air cooling alone. Due to the modular arrangement of chambers 22 and associated components, arrangements may be changed over time. This also permits different types of electronic devices 28, e.g., networking and computer components, to be intermingled.

As previously noted, the chiller unit 27 (schematically shown in FIG. 5) is positioned outside of the building 21. One or more primary cooling liquid lines 48 extend from the chiller unit 27 to a location positioned above the insulated chambers 22, and back to the chiller unit 27. The chiller unit 27 is configured to receive heated liquids from the primary cooling liquid lines 48, to cool the liquid and to emit the cooled liquid back into the primary cooling liquid lines 48 for use in the data center facility 20. The chiller unit 27 is configured to selectively cool the liquid to desired/pre-determined temperatures. As illustrated in FIG. 3, the primary cooling liquid lines 48 may be segmented into any number of respective cooling systems with different temperatures and pressures. According to embodiments, five sets of primary cooling liquid lines 48A, 48B, 48C, 48D, 48E are provided to service different combinations of chambers 22 with different requirements. As best shown in FIGS. 5 and 14, a series of first secondary cooling liquid lines 53 branch from the primary cooling liquid lines 48 into a liquid coolant delivery assembly affixed within the front chamber spaces 24A of the insulated chambers 22 for cooling the electronic devices 28, and back to the primary cooling liquid lines 48 from the liquid coolant delivery assembly. A series of second secondary cooling liquid lines 35 branch from the primary cooling liquid lines 48 into a series of HVAC units 40 for transferring heat away from the HVAC units 40. According to embodiments, the cooling lines 48, 53, 35 may have different pressures and temperatures than one another based on specific needs of respective chambers 22. As shown in FIGS. 6 and 14 chilled water valves 59 may be connected to any number of the primary and/or secondary cooling liquid lines 48, 53, 35 to control a flow of the chilled water passing through the cooling liquid lines 48, 53, 35. Any number of chilled water valves 59 may be used and they may be at various locations.

As shown in FIG. 5, liquid cooling hoses 55 (schematically shown) extend from the second secondary lines 35 and to liquid cooling systems 63 of the owner of the electronic devices 28, which then provide direct-to-chip liquid cooling to the electronic devices 28. Accordingly, the liquid cooling hoses 55 permit an owner of the electronic devices 28 to interchangeably connect preferred liquid cooling mechanisms to the electronic devices 28. The liquid cooling hoses 55 are routed from the electronic devices 28 back to the primary cooling liquid lines 48 to permit liquid that has been heated by the electronic devices 28 to be routed back to the chiller unit 51 for cooling and re-use of the liquid. Like the power units 46, redundant lines may be used for any of the primary cooling liquid lines 48, secondary cooling liquid lines 53, 35 and liquid cooling hoses 55 to provide backup operations in the event of failure of any of the others. The compact and simple arrangement of the cooling lines 48, 53, 35 and associated hoses 55 permits additional cooling lines 48, 53, 35 and hoses 55 to be added as needed to optimize cooling demands. Any number of separate fluidic systems, i.e., groups of primary and or secondary lines 48, 53, 35 may be used for variability in pressure and temperatures of cooling liquids. Pipe sizes of the primary and secondary lines 48, 53, 35 and valves 59 may vary from line to line to vary ranges of flow rates to provide specific cooling effects. Finally, the overhead arrangement of the primary lines 48 does not restrict airflow into the chambers 22 from the HVAC units 40.

The liquid in the primary and secondary lines 48, 53 and cooling hoses 55 may vary in temperature from line to line depending on specific needs of specific chambers 22. According to a preferred embodiment, the temperature of the primary and secondary lines 48, 53 and cooling hoses 55 is somewhere in the range of 74 to 94 degrees Fahrenheit to provide an optimal balance of chip cooling, without using excess energy in cooling the liquid. Typical temperature of primary and secondary lines 48, 35 is somewhere in the range of 55 to 59 degrees Fahrenheit in order provide an optimal balance of hybrid air cooling, without using excess energy in cooling the liquid.

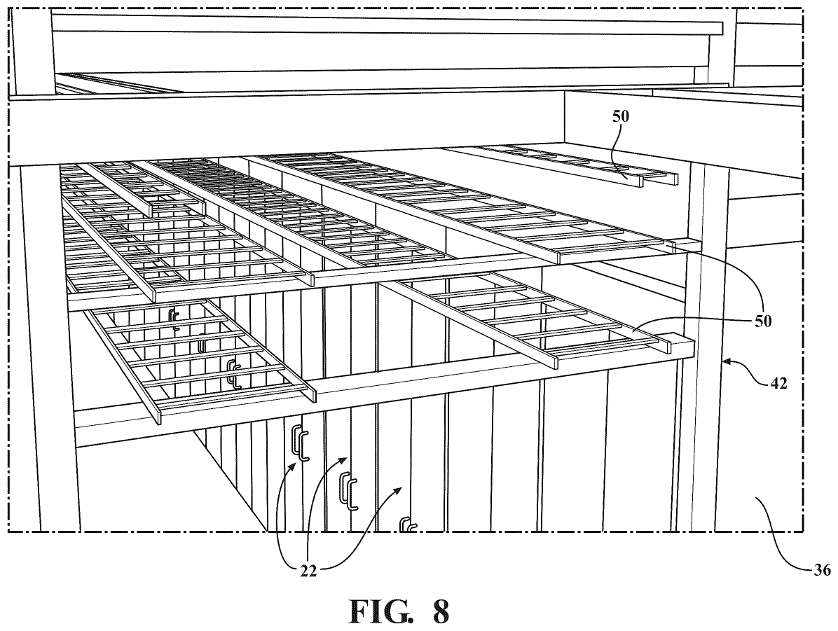

As shown in FIGS. 3-5 and 8, ladder racks 50 are positioned across the support frame 42 a level below the primary cooling liquid lines 48 to secure and guide internet connectivity, and/or other cables which are connected to the electronic devices 28. As illustrated in FIG. 8, the ladder racks 50 may be configured with ladders 50 of different sized-like one 16″ ladder rack layer and one 12″ ladder rack layer associated with all chambers 22 to provide ample space for network connectivity. Any number of tiers of ladder racks 50 may be stacked relative to one another. This may be on the hot sides (along the rear chamber space 24B) of the chambers 22, the cool sides (along the front chamber space 24A), or both. The arrangement of the ladder racks 50 permits networking racks to be housed inside the chambers 22 without any modifications from rack locations.

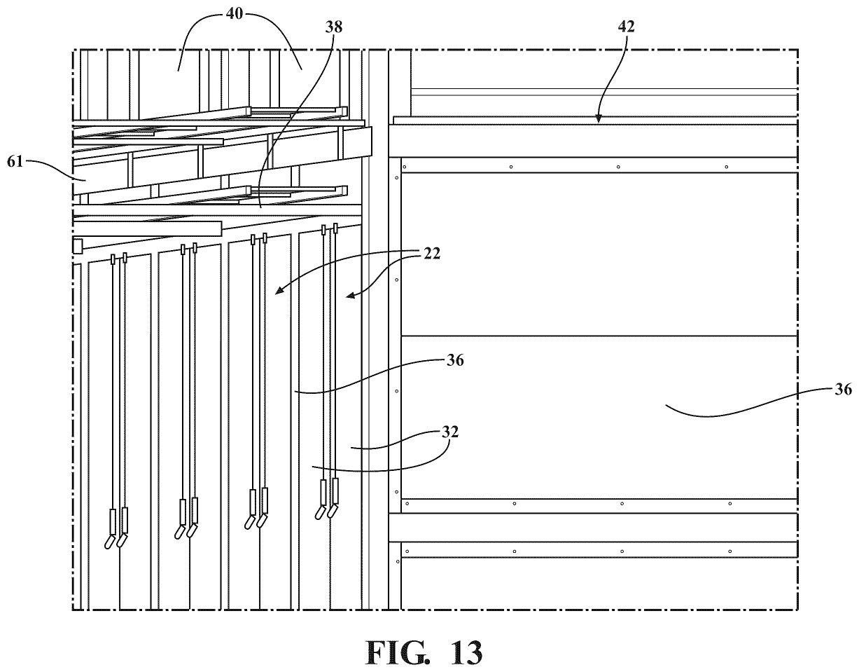

According to embodiments, the chambers 22 may be made of a water-resistant and/or water-proof material, which is of particular importance because it protects the electronic devices 29 inside the chambers 22 from water damage due to condensation from the cooling lines 48, 53 above. Furthermore, as best shown in FIG. 13, condensate drip trays 61 may be positioned beneath the HVAC units 40 for collecting and draining water from the cooling coils 45 of the HVAC units 40. One or more condensate hoses (not shown) may be configured to fluidly connect the HVAC unit 40 to the condensate drip trays 61 to permit the condensate drop trays 61 to receive the water. The condensate drip trays 61 may be configured to pass the water outside of the building or to any other receptacle 21.

As illustrated in FIG. 4, adjacent chambers 22 may have one or more openings 52 in the sidewall 36 defined above the cabinets 26 to permit the chambers 22 to be fluidly connected to one another. More particularly a front opening 52 may be defined between adjacent front chamber spaces 24A of adjacent chambers 22 to permit cooled air of the front chamber spaces 24A to be pooled together to provide a redundant cooling effect in the event that the HVAC units 40 of any given chamber 22 fail. Likewise, a rear opening (not shown) may be defined between adjacent rear chamber spaces 24B of adjacent chambers 22 to permit heated air of the rear chamber spaces 24B to be pooled together for redundancy, such as in a scenario in which an intake fan of an HVAC unit 40 is not operational. The front and rear openings 52 may collectively define continuous plenums extending across upper regions of adjacent chambers 22. FIG. 4 shows a cold air plenum 54 that is comprised of several front gaps 52 that are located between a number of adjacent chambers 22. Any number of chambers 22 may share hot and cold air plenums 54 in the same manner, e.g., 20-24 adjacent chambers 22. The front and rear chamber spaces 24A, 24B remain sealed relative to one another in all cases so as to prevent the mixing of hot and cold air.

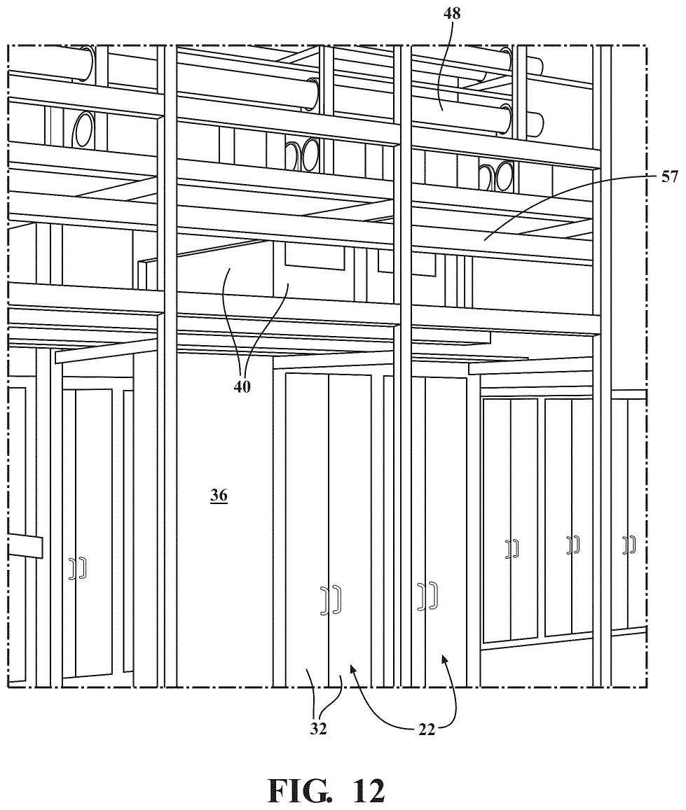

As shown in FIG. 12, a series of network trays 57 may be coupled to the support frame 42. The network trays 57 are configured to house various types of cables, e.g., networking cables, in a protected manner. Various numbers and configurations of network trays 57 may be used.

The modular design of the chambers 22, support frame 42 and associated components permits the chambers 22 to be built rapidly, in various settings, such as in pre-engineered metal buildings or existing buildings.

Obviously, many modifications and variations of the present invention are possible in light of the above teachings and may be practiced otherwise than as specifically described while within the scope of the appended claims. These antecedent recitations should be interpreted to cover any combination in which the inventive novelty exercises its utility.

Clearly, changes may be made to what is described and illustrated herein without, however, departing from the scope defined in the accompanying claims. The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in any embodiment, even if not specifically shown or described. The same may also be varied in many ways. Such variations are not to be regarded as a departure from the disclosure, and all such modifications are intended to be included within the scope of the disclosure.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

What is claimed is:

1. A data center facility, comprising:
a plurality of insulated chambers each defining a compartment and having at least one front door and at least one rear door opposite the front door;
a plurality of electronic equipment cabinets each positioned in the compartment of one of the chambers, the electronic equipment cabinets configured to hold a plurality of electronic devices;
the compartment of each of the chambers divided into a front chamber space and a rear chamber space;
an air cooling assembly configured to emit cooled air into the front chamber space to cool the electronic devices, and to remove air that has been heated by the electronic devices from the rear chamber space; and
a liquid coolant delivery assembly configured to releasably connect to a liquid cooling unit of the electronic devices for cooling the electronic devices.

2. The data center facility as set forth in claim 1, wherein each of the chambers includes a dividing panel positioned in the compartment about the electronic equipment cabinet to divide the chamber into the front and rear chamber spaces.

3. The data center facility as set forth in claim 1, wherein the air cooling assembly includes at least one HVAC unit positioned above at least one of the chambers.

4. The data center facility as set forth in claim 3, wherein each of the chambers has a ceiling panel closing a top of the compartment, and wherein the ceiling panel defines a front cooling opening over the front chamber space and a return air opening over the rear chamber space, and wherein the at least one HVAC unit is configured to draw air through the return air opening, to cool the air and to emit the cooled air through the front cooling opening.

5. The data center facility as set forth in claim 3, wherein the at least one HVAC unit includes a plurality of HVAC units, and wherein one of the HVAC units is positioned above each of the chambers.

6. The data center as set forth in claim 1, wherein at least two of the front chamber spaces of at least two of the chambers are fluidly connected to one another to permit cooled air to pass between the at least two front chambers spaces of the at least two chambers.

7. The data center as set forth in claim 1, wherein at least two of the rear chamber spaces of at least two of the chambers are fluidly connected to one another to permit heated air to pass between the at least two rear chambers spaces of the at least two chambers.

8. The data center facility as set forth in claim 1, further including a chiller and a plurality of primary lines extending from the chiller to a location above the chambers and back to the chiller, and fluidly connected to the liquid coolant delivery assembly to deliver cooled liquids to the liquid coolant delivery assembly.

9. The data center facility as set forth in claim 8, wherein a plurality of secondary lines fluidly connect the primary lines to the liquid coolant delivery assembly.

10. The data center facility as set forth in claim 8, wherein a plurality of secondary lines fluidly connect the primary lines to the air cooling assembly for cooling the air cooling assembly.

11. The data center facility as set forth in claim 8, wherein the plurality of primary lines includes a plurality of groups of primary lines configured to transport the liquid at different temperatures and pressures to selectively cool the chambers associated with each group.

12. A data center facility, comprising:
a plurality of insulated chambers each defining a compartment;
a plurality of electronic equipment cabinets each positioned in the compartment of one of the insulated chambers, the electronic equipment cabinets configured to hold a plurality of electronic devices;
a liquid coolant delivery assembly configured to releasably connect to liquid cooling units of the electronic devices for cooling the electronic devices; and
the liquid coolant delivery assembly including a plurality of liquid coolant delivery systems for connecting to a plurality of the cooling units of the electronic devices to provide different cooling effects for respective electronic devices.

13. The data center facility as set forth in claim 12, wherein the liquid coolant delivery assembly further includes a chiller, and wherein the plurality of liquid coolant delivery systems includes a plurality of groups of primary lines connected to the chiller and configured to transport the liquid at different temperatures and pressures to selectively cool the chambers associated with each group of primary lines.

14. The data center facility as set forth in claim 13, wherein the liquid coolant delivery assembly further includes a plurality of secondary lines fluidly connect the plurality of primary lines to the plurality of cooling units.

15. A data center facility, comprising:
a plurality of insulated chambers each defining a compartment;
a plurality of electronic equipment cabinets each positioned in the compartment of one of the insulated chambers, the electronic equipment cabinets configured to hold a plurality of electronic devices;
each of the insulated chambers including an insulated dividing panel being sealingly positioned in the compartment of the insulated chamber about the electronic equipment cabinet and dividing the compartment into a front chamber space and a rear chamber space; and
a plurality of air cooling assemblies each positioned above one of the chambers and configured to emit cooled air into the front chamber space to cool the electronic devices, and to remove air that has been heated by the electronic devices from the rear chamber space.

16. The data center facility as set forth in claim 15, wherein each of the air cooling assemblies includes a plurality of HVAC units each positioned above at least one of the chambers.

17. The data center facility as set forth in claim 16, wherein each of the chambers has a ceiling panel closing a top of the compartment, and wherein the ceiling panel defines a front cooling opening over the front chamber space and a return air opening over the rear chamber space, and wherein each of the air cooling assemblies are configured to draw air through the return air opening, to cool the air and to emit the cooled air through the front cooling opening.

18. The data center as set forth in claim 15, wherein at least two of the front chamber spaces of at least two of the chambers are fluidly connected to one another to permit cooled air to pass between the at least two front chambers spaces of the at least two chambers.

19. The data center as set forth in claim 15, wherein at least two of the rear chamber spaces of at least two of the chambers are fluidly connected to one another to permit heated air to pass between the at least two rear chambers spaces of the at least two chambers.

20. A data center facility, comprising:
a plurality of insulated chambers each defining a compartment and having at least one door;
the plurality of insulated chambers positioned in a plurality of rows positioned in parallel relationship with one another;
a plurality of electronic equipment cabinets each positioned in the compartment of one of the insulated chambers, the electronic equipment cabinets configured to hold a plurality of electronic devices; and
the at least one door of each of the cabinets includes a pair of doors configured to rotate in opposite directions from one another between an open position and a closed position, wherein edges of the doors are configured to be positioned adjacent to, and aligned with one another when the doors are in the closed position.

21. The data center facility as set forth in claim 1, wherein the at least one door of each of the chambers includes a pair of front doors and a pair of rear doors on an opposite side of the chamber as the front doors.
